(19) United States
(12) Patent Application Publication
(10) Pub. No.: US 2025/0389799 A1
(43) Pub. Date: Dec. 25, 2025

(54) MAGNETIC RESONANCE IMAGING METHOD AND MAGNETIC RESONANCE IMAGING SYSTEM

(71) Applicant: GE Precision Healthcare LLC, Waukesha, WI (US)

(72) Inventor: Lei Gao, Beijing (CN)

(21) Appl. No.: 19/247,373

(22) Filed: Jun. 24, 2025

(30) Foreign Application Priority Data
Jun. 25, 2024 (CN) 202410830846.1

(51) Int. Cl. G01R 33/36

(52) U.S. Cl. CPC G01R 33/3607

(57) ABSTRACT

A magnetic resonance imaging method and a magnetic resonance imaging system are provided. The method includes: determining a B1 maximum value of a radio-frequency (RF) field; adjusting a profile of an RF pulse according to the B1 maximum value; and generating and transmitting an adjusted RF pulse, acquiring a magnetic resonance signal, and reconstructing a magnetic resonance image according to the magnetic resonance signal.

### CROSS REFERENCE TO RELATED APPLICATIONS

The present application claims priority and benefit of Chinese Patent Application No. 202410830846.1 filed on Jun. 25, 2024, which is incorporated herein by reference in its entirety.

### TECHNICAL FIELD

Embodiments of the present application relate to the technical field of medical devices, and in particular to a magnetic resonance imaging method and a magnetic resonance imaging system.

### BACKGROUND

Magnetic resonance imaging (MRI) systems have been widely used in the field of medical diagnosis. An MRI system typically includes a main magnet, a radio-frequency (RF) generator, an RF power amplifier, an RF transmit coil, a surface coil, a gradient coil driver, a gradient coil assembly, and the like. MRI utilizes the main magnet to generate a static magnetic field B0, and when a subject to be examined is located in the static magnetic field B0, nuclear spins associated with hydrogen nuclei in tissues of the subject to be examined are polarized, so that the tissue to be examined macroscopically generates a longitudinal magnetization vector. The RF generator generates an RF pulse, such as an RF excitation pulse. The RF power amplifier is configured to amplify a low-power RF signal generated by the RF generator to generate a high-power RF signal that can excite a human tissue. The high-power RF signal may be inputted to the RF transmit coil via an RF transmission line, so that the RF transmit coil transmits an RF field B1 orthogonal to the field B0 to the subject to excite atomic nuclei in the aforementioned resonant region to generate a transverse magnetization vector. After the RF field B1 is removed, the transverse magnetization vector is attenuated in a spiral manner, and a magnetic resonance signal is generated. The magnetic resonance signal can be acquired for reconstructing an image of a tissue part to be examined.

### SUMMARY

Embodiments of the present application provide a magnetic resonance imaging method and a magnetic resonance imaging system.

According to an aspect of the embodiments of the present application, a magnetic resonance imaging method is provided. The method comprises: determining a B1 maximum value of an RF field; adjusting a profile of an RF pulse according to the B1 maximum value; and generating and transmitting an adjusted RF pulse, acquiring a magnetic resonance signal, and reconstructing a magnetic resonance image according to the magnetic resonance signal.

According to an aspect of the embodiments of the present application, a magnetic resonance imaging system is provided, the system comprises: a scanning unit; and a controller, configured to perform the magnetic resonance imaging method described in the previous aspect.

One of the beneficial effects of the embodiments of the present application is that: by means of the above embodiments, the profile of the RF pulse is adjusted according to the real-time B1 maximum value. As a result, the capability of the RF power amplifier can be fully utilized, the RF pulse waveform can be optimized, and a better excitation or spin echo or saturation profile can be obtained, thereby improving the image quality and reducing the scanning time.

With reference to the following description and drawings, specific implementations of the embodiments of the present application are disclosed in detail, and the way in which the principles of the embodiments of the present application can be employed are illustrated. It should be understood that the embodiments of the present application are not limited in scope thereby. Within the scope of the spirit and clauses of the appended claims, the embodiments of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of a magnetic resonance imaging method according to an embodiment of the present application;

FIG. 3 is a schematic diagram of an implementation method of step 201 according to an embodiment of the present application;

FIG. 4 is a schematic diagram of an implementation method of step 202 according to an embodiment of the present application;

FIG. 5 is a time-domain schematic diagram of an original RF pulse and an adjusted RF pulse according to an embodiment of the present application;

FIG. 6 is a frequency-domain schematic diagram of an original RF pulse and an adjusted RF pulse according to an embodiment of the present application;

FIG. 7 is a time-domain schematic diagram of an original RF pulse and an adjusted RF pulse according to an embodiment of the present application;

FIG. 8 is a frequency-domain schematic diagram of an original RF pulse and an adjusted RF pulse according to an embodiment of the present application;

FIG. 9 is a schematic diagram of a magnetic resonance imaging method according to an embodiment of the present application;

FIG. 10 is time-domain and frequency-domain schematic diagrams of two types of RF pulses according to an embodiment of the present application; and

FIG. 11 is time-domain and frequency-domain schematic diagrams of two types of RF pulses according to an embodiment of the present application.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first” and “second” and so on are used to distinguish different elements from one another by title, but do not represent the spatial arrangement, temporal order, or the like of the elements, and the elements should not be limited by said terms. The term “and/or” includes any one of and all combinations of one or more associated listed terms. The terms “comprise”, “include”, “have”, etc., refer to the presence of stated features, elements, components, or assemblies, but do not exclude the presence or addition of one or more other features, elements, components, or assemblies.

In the embodiments of the present application, the singular forms “a” and “the” or the like include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ”, and the term “based on” should be construed as “at least in part based on . . . ”, unless otherwise clearly specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

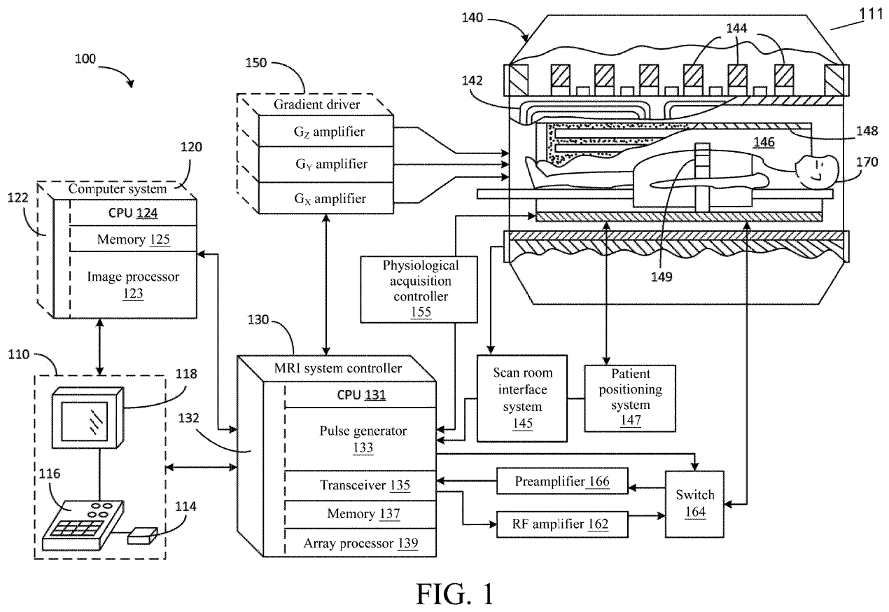

For ease of understanding, FIG. 1 shows a magnetic resonance imaging (MRI) system 100 according to some examples of the present invention.

The MRI system 100 includes a scanning unit 111. The scanning unit 111 is used to perform a magnetic resonance scan on a subject (for example, a human body) 170 to generate image data of a region of interest of the subject 170. The region of interest may be a predetermined anatomical site or anatomical tissue.

Operation of the MRI system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118. The computer system 120 includes a plurality of components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate MRI system controller 130.

The MRI system controller 130 includes a set of components that communicate with one another by means of an electrical and/or data connection module 132. The connection module 132 may employ a direct wired connection, a fiber optic connection, a wireless communication link, etc. The MRI system controller 130 may include a CPU 131, a sequential pulse generator 133 that communicates with the operator workstation 110, a transceiver (or an RF transceiver) 135, a memory 137, and an array processor 139. In some embodiments, the sequential pulse generator 133 may be integrated into a resonance assembly 140 of the scanning unit 111 of the MRI system 100. The MRI system controller 130 may receive a command from the operator workstation 110, and is coupled to the scanning unit 111, to indicate an MRI scan sequence that is to be performed during an MRI scan, so as to control the scanning unit 111 to execute the described magnetic resonance scan procedure. The MRI system controller 130 is further coupled to and communicates with a gradient driver system 150, and the gradient driver system is coupled to a gradient coil assembly 142 to generate a magnetic field gradient during the MRI scan.

The sequential pulse generator 133 may further receive data from a physiological acquisition controller 155. The physiological acquisition controller receives signals from a plurality of different sensors (for example, electrocardiogram (ECG) signals from electrodes attached to a patient), the sensors being connected to the subject or patient 170 undergoing the MRI scan. The sequential pulse generator 133 is coupled to and communicates with a scan room interface system 145, and the scan room interface system receives signals from various sensors associated with the state of the resonance assembly 140. The scan room interface system 145 is further coupled to and communicates with a patient positioning system 147, and the patient positioning system sends and receives signals to control the movement of a patient table to a desired position to perform the MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} gradient amplifiers excites a corresponding gradient coil in the gradient coil assembly 142, to generate a magnetic field gradient used to spatially encode an MR signal during an MRI scan. The gradient coil assembly 142 is disposed within the resonance assembly 140, the resonance assembly further includes a superconducting magnet having a superconducting coil 144, and during operation, the superconducting coil provides a static uniform longitudinal magnetic field Bo that runs through a cylindrical imaging volume 146. The resonance assembly 140 further includes an RF body coil 148, which, in operation, provides a transverse magnetic field B₁, the transverse magnetic field B₁ being substantially perpendicular to B₀ throughout the entire cylindrical imaging volume 146. The resonance assembly 140 may further include an RF surface coil 149, and the RF surface coil is used to image different anatomical structures of the patient undergoing the MRI scan. The RF body coil 148 and the RF surface coil 149 may be configured to operate in a transmit and receive mode, a transmit mode, or a receive mode.

The x direction may also be referred to as a frequency encoding direction or a kₓ direction in k-space. The y direction may be referred to as a phase encoding direction or a k_{y} direction in the k-space. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses that are amplified by an RF amplifier 162 and provided to the RF body coil 148 by means of a transmit/receive switch (T/R switch) 164.

As described above, the RF body coil 148 and the RF surface coil 149 may be used to transmit an RF excitation pulse and/or receive obtained MR signals from the patient undergoing the MRI scan. MR signals emitted by excited nuclei in the patient of the MRI scan may be sensed and received by the RF body coil 148 or the RF surface coil 149 and sent back to a pre-amplifier 166 by means of the T/R switch 164. The T/R switch 164 may be controlled by a signal from the sequential pulse generator 133 to electrically connect, when in the transmit mode, the RF amplifier 162 to the RF body coil 148, and to connect, when in the receive mode, the pre-amplifier 166 to the RF body coil 148. The T/R switch 164 may further enable the RF surface coil 149 to be used in the transmit mode or the receive mode.

In some embodiments, the MR signals sensed and received by the RF body coil 148 or the RF surface coil 149 and amplified by the pre-amplifier 166 are stored as a raw k-space data array in the memory 137 for post-processing. A reconstructed magnetic resonance image may be obtained by transforming/processing the stored raw k-space data.

In some embodiments, the MR signals sensed and received by the RF body coil 148 or the RF surface coil 149 and amplified by the pre-amplifier 166 are demodulated, filtered, and digitized in a receiving portion of the transceiver 135, and transmitted to the memory 137 in the MRI system controller 130. For each image that is to be reconstructed, the data is rearranged into a separate k-space data array, each of the separate k-space data arrays is inputted into the array processor 139, and the array processor is operated to transform the data into an array of image data by means of a Fourier transform.

The array processor 139 uses a transform method, most commonly a Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 1 is intended for illustration. Suitable MRI systems may include more, fewer, and/or different components.

The MRI system controller 130 and the image processor 128 may separately or collectively include a computer processor and a storage medium. The storage medium records a predetermined data processing program that is to be executed by the computer processor. For example, the storage medium may store a program used to implement scanning (for example, a scan procedure and an imaging sequence), image reconstruction, image processing, etc. For example, the storage medium may store a program used to implement the magnetic resonance imaging method according to the examples of the present invention. The above storage medium may include, for example, a ROM, a floppy disk, a hard disk, an optical disk, a magneto-optical disk, a CD-ROM, or a non-volatile memory card.

The aforementioned “imaging sequence” (also referred to below as a scan sequence or a pulse sequence) is a combination of pulses that have specific amplitudes, widths, directions, and time sequences, and that are applied when a magnetic resonance imaging scan is performed. These pulses typically may include, for example, a radio-frequency pulse and a gradient pulse. The radio-frequency pulses may include, for example, radio-frequency excitation pulses, radio-frequency refocusing pulses, inverse recovery pulses, etc. The gradient pulses may include, for example, the aforementioned gradient pulse used for layer selection, gradient pulse used for phase encoding, gradient pulse used for frequency encoding, gradient pulse used for phase shifting (phase shift), gradient pulse used for dispersion of phases (dephasing), etc.

Typically, a plurality of scan sequences can be preset in the magnetic resonance system, so that a sequence suitable for clinical detection requirements can be selected. The clinical detection requirements may include, for example, an imaging site, an imaging function, an imaging effect, and the like.

Generally, the size of a B1 field may represent the intensity of an RF pulse when a magnetic resonance coil transmits. A B1 field maximum value (hereinafter referred to as B1ₘₐₓ) may represent a maximum amplitude of an RF pulse, and B1ₘₐₓ is limited by a maximum power of the RF power amplifier. The smaller the maximum power of the RF power amplifier, the lower the cost, but at the cost of a decrease in B1ₘₐₓ. The decrease in B1ₘₐₓ leads to a longer echo time and a longer echo spacing.

In most clinical applications, the RF power amplifier cannot output the maximum power. This is because when scan subjects are different or scan positions are different, different output powers are required to generate the same B1. To ensure the normal operation of the RF power amplifier, a certain B1 margin needs to be reserved to adapt to the conditions of various scan subjects or scan sites.

At present, an RF pulse design in a scan sequence has a specific B1 max, and due to the constraint of reservation of a B1ₘₐₓ margin, optimization of the RF pulse cannot be achieved, the capability of the RF power amplifier cannot be fully utilized, and performance optimization cannot be achieved. In view of at least one of the above problems, the embodiments of the present application provide a magnetic resonance imaging method and a magnetic resonance imaging system. Description is made below in conjunction with the embodiments.

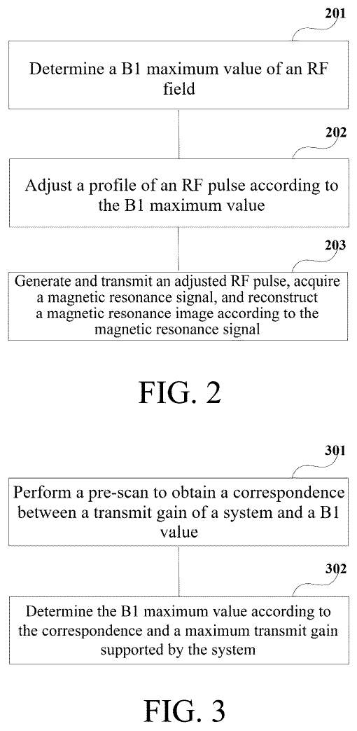

The embodiments of the present application provide a magnetic resonance imaging method. FIG. 2 is a schematic diagram of the magnetic resonance imaging method according to an embodiment of the present application. As shown in FIG. 2, the method includes at step 201: determining a B1 maximum value of an RF field. Further at step 202: a profile of an RF pulse is adjusted according to the B1 maximum value; and at step 203: an adjusted RF pulse is generated and transmitted, a magnetic resonance signal is acquired, and a magnetic resonance image is reconstructed according to the magnetic resonance signal.

As described above, in order to ensure the normal operation of the RF power amplifier, a certain B1 margin needs to be reserved to adapt to the conditions of various scan subjects or scan sites. Therefore, when a magnetic resonance imaging system is in operation, an RF pulse is not transmitted at a full-load maximum power, and at this time, a generated RF field B1 value is not a B1 maximum value that can be theoretically generated by the magnetic resonance imaging system. In 201, the B1 maximum value of the RF field that can be theoretically generated by a current magnetic resonance imaging system may be determined by means of estimation.

FIG. 3 is a schematic diagram of an implementation method of step 201 according to an embodiment of the present application. As shown in FIG. 3, the method includes: at step 301: performing a pre-scan to obtain a correspondence between a transmit gain of a system and a B1 value; and at step 302: determining the B1 maximum value according to the correspondence and a maximum transmit gain supported by the system.

In some embodiments, the pre-scan needs to be performed before a formal diagnostic scan. When the pre-scan is performed, a subject under examination needs to enter a scanner bore, and after scan parameters are set, a scan sequence for the pre-scan is transmitted, shimming data is determined, a center frequency is corrected, a receive gain is determined, a phase is calibrated, and the like. Additionally, when the pre-scan is performed, an RF pulse of a predetermined waveform may be transmitted at a transmit power corresponding to a set transmit gain TGᵢₙᵢₜ. The embodiments of the present application impose no limitations on the predetermined waveform or the transmit gain TGᵢₙᵢₜ. A magnetic resonance signal during the pre-scan is acquired, and a phase of the magnetic resonance signal is measured. A maximum amplitude (peak value) B1ᵢₙᵢₜ of the RF pulse of the predetermined waveform may be calculated according to the phase in combination with the Bloch-Siegert shift method. For details, reference may be made to the related art. Thereby, a pair of TGᵢₙᵢₜ and B1ᵢₙᵢₜ may be obtained. The correspondence between the transmit gain of the system and the B1 value is shown in the following Equation (1), and after TGᵢₙᵢₜ and B1ᵢₙᵢₜ are determined, the correspondence is determined.

$$B 1 = B {1}_{init} / {10}^{( {TG}_{init} - TG ) / 200} \qquad Equation ( 1 )$$

In some embodiments, in 302, a transmit power at which an attenuation value of an RF attenuator in the RF power amplifier is 0 is determined, and the transmit power is the maximum transmit power, so that a maximum transmit gain TGₘₐₓ supported by the system corresponding to the maximum transmit power can be determined. The B1 maximum value B1ₘₐₓ of the RF field that can be theoretically generated by the current magnetic resonance system can be obtained by substituting TGₘₐₓ into Equation (1).

In some embodiments, the RF pulses in the scan sequence may include at least one of an excitation pulse, a refocusing pulse, a saturation pulse, etc. For example, the RF pulses may include only an excitation pulse, or may include an excitation pulse and a refocusing pulse, etc., which are not enumerated herein. For example, the RF pulses include a 90° (or less) excitation pulse and a 180° refocusing pulse spaced by ½ echo time from the excitation pulse. The scan sequence may further include a gradient pulse applied along with the RF pulse and used for layer selection, a gradient pulse for frequency encoding, and a gradient pulse for phase encoding. Optionally, the scan sequence may further include a gradient pulse not applied along with the radio-frequency pulse. The examples of the present application are not limited thereto. For example, the scan sequence may include a gradient echo (GRE) pulse sequence, a fast spin echo (FSE) pulse sequence, etc. Examples are not listed one by one herein.

In some embodiments, the profile of the RF pulse may be in the shape of a sinc wave or an SLR (Shinnar-Le Roux) wave, which is not limited in the embodiments of the present application.

In some embodiments, the following parameters may be set in the magnetic resonance imaging system to determine the waveform and timing of the RF pulse: RF pulse type (excitation, refocusing, saturation, etc.), time-bandwidth product (product of the duration of the RF pulse in the time domain and the bandwidth of the RF pulse in the frequency domain), passband ripple coefficient, stopband ripple coefficient, duration, resolution, etc., which is not exemplified one by one herein. Initial values of the aforementioned parameters may be set by default to be associated with a selected scan protocol, or may also be set by an operator.

In some embodiments, in order to fully utilize the capability of the RF power amplifier, in 202, the profile of the RF pulse can be adjusted according to the B1 maximum value, that is, the initial values of the aforementioned parameters are no longer used, instead, at least one of the aforementioned parameters is adjusted according to the B1 maximum value, thereby changing the profile of the RF pulse.

In some embodiments, adjusting the profile of the RF pulse according to the B1 maximum value includes adjusting a time-bandwidth product of the RF pulse according to the B1 maximum value. The adjusting the time-bandwidth product of the RF pulse includes increasing the time-bandwidth product of the RF pulse, that is, the time-bandwidth product of the adjusted RF pulse is greater than the time-bandwidth product of the RF pulse before adjustment. An increase in the time-bandwidth product includes: the duration of the RF pulse before adjustment in the time domain is the same as the duration of the adjusted RF pulse in the time domain, and the bandwidth of the adjusted RF pulse in the frequency domain is greater than the bandwidth of the RF pulse before adjustment in the frequency domain, but the embodiments of the present application are not limited thereto. The duration may also be increased or decreased, provided that the time-bandwidth product is increased, which is not exemplified one by one herein.

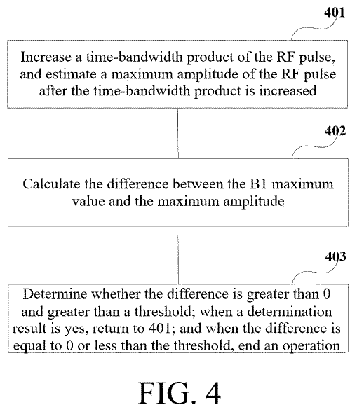

FIG. 4 is a schematic diagram of an implementation method of step 202 according to an embodiment of the present application. As shown in FIG. 4, the method includes: at step 401: increasing the time-bandwidth product of the RF pulse, and estimating a maximum amplitude of the RF pulse after the time-bandwidth product is increased. The method further includes at step 402: calculating the difference between the B1 maximum value and the maximum amplitude. At step 403, the method includes: determining whether the difference is greater than 0 and greater than a threshold; when a determination result is yes, returning to 401; and when the difference is equal to 0 or less than the threshold, ending an operation.

In some embodiments, a step size for each time-bandwidth product increase may be set to S; with the initial value of the time-bandwidth product set to P, the time-bandwidth product may be adjusted to P+S for the first time, and a maximum amplitude RF1 of the adjusted RF pulse is calculated according to the adjusted time-bandwidth product, so that a waveform area of the adjusted RF pulse in the time domain is equal to that of the RF pulse before adjustment in the time domain. The difference between B1ₘₐₓ and RF1 is calculated, and it is determined whether the difference is greater than 0 and greater than a threshold T, wherein the threshold may be determined as required, e.g., the threshold may be set to a value close to 0. The embodiments of the present application are not limited thereto. When a determination result is that the difference is equal to 0 or less than the threshold T, it indicates that a maximum amplitude of a currently adjusted RF pulse is equal to the B1 maximum value, or asymptotically approaches the B1 maximum value. At this time, the capability of the RF power amplifier is fully utilized, and the adjustment may be stopped. When the determination result is that the difference is greater than 0 and greater than the threshold T, it indicates that the maximum amplitude of the RF pulse still has not reached B1ₘₐₓ, there is still a certain difference between the maximum amplitude of the currently adjusted RF pulse and the B1 maximum value, the RF pulse still has adjustment potential, and the capability of the RF power amplifier is not yet fully utilized. The time-bandwidth product may be adjusted to P+2S according to the foregoing set step length. A maximum amplitude RF2 of the RF pulse is calculated according to the adjusted time-bandwidth product, so that the waveform area of the adjusted RF pulse in the time domain is equal to the waveform area of the RF pulse before adjustment in the time domain. The difference between B1ₘₐₓ and RF2 is calculated, and the aforementioned process is repeated until the determination result shows that the difference is equal to 0 or less than the threshold T.

The foregoing is merely illustrative. The embodiments of the present application are not limited thereto. For example, correspondences between different B1 maximum values and time-bandwidth products may be predetermined, and a time-bandwidth product corresponding to the B1 maximum value determined in step 201 is determined according to the correspondences and the B1 maximum value determined in step 201, thereby adjusting the profile of the RF pulse, which will not be repeated here.

How to adjust the profile of the RF pulse will be described below with reference to the accompanying drawings.

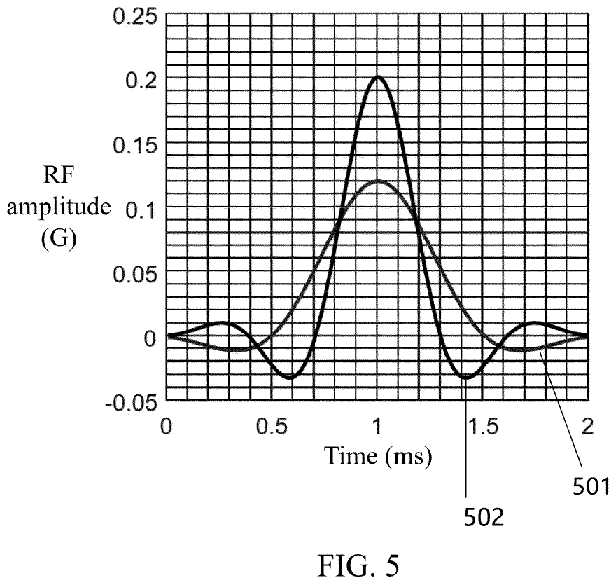

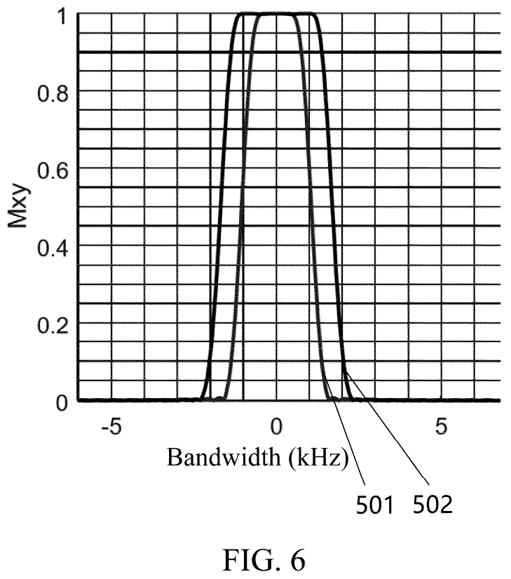

FIG. 5 is a time-domain schematic diagram of an original RF pulse 501 and an adjusted RF pulse 502 according to an embodiment of the present application. FIG. 6 is a frequency-domain schematic diagram of an original RF pulse 601 and an adjusted RF pulse 602 according to an embodiment of the present application. The time-bandwidth product may be approximately regarded as equal to the number of zero-crossing points of the waveform of the RF pulse in the time domain (the number of intersections of a waveform and a time axis). Increasing the time-bandwidth product raises the number of the zero-crossing points, which means that the number of peaks and troughs of the waveform of the RF pulse will increase, thereby changing the profile of the RF pulse. As shown in FIG. 5, using a 90° excitation pulse being used as the RF pulse as an example, the number of zero-crossing points before adjustment is 4, the number of zero-crossing points after adjustment is 6, the time-bandwidth product of the adjusted RF pulse is greater than the time-bandwidth product of the RF pulse before adjustment, the duration of the adjusted RF pulse in the time domain is equal to the duration of the RF pulse before adjustment in the time domain, the maximum amplitude of the RF pulse before adjustment is, for example, 0.12 G, the maximum amplitude of the adjusted RF pulse is equal to the B1 maximum value, that is, 0.2 G, and the waveform area of the adjusted RF pulse in the time domain is equal to the waveform area of the RF pulse before adjustment in the time domain. As shown in FIG. 6, for the RF pulse shown in FIG. 5, since the duration of the adjusted RF pulse in the time domain is equal to the duration of the RF pulse before adjustment in the time domain, the bandwidth of the adjusted RF pulse in the frequency domain is greater than the bandwidth of the RF pulse before adjustment in the frequency domain.

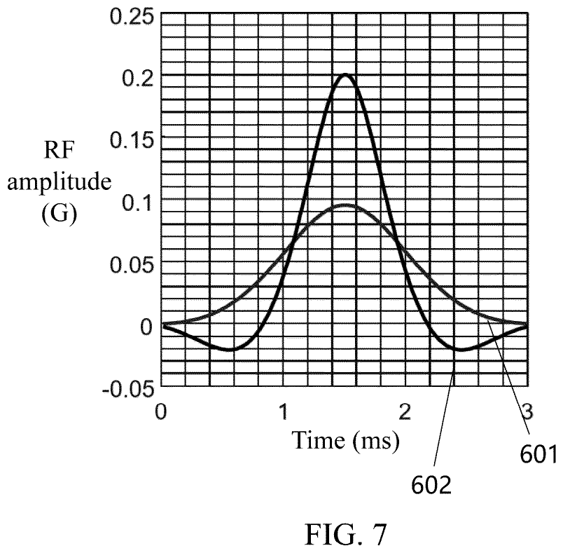

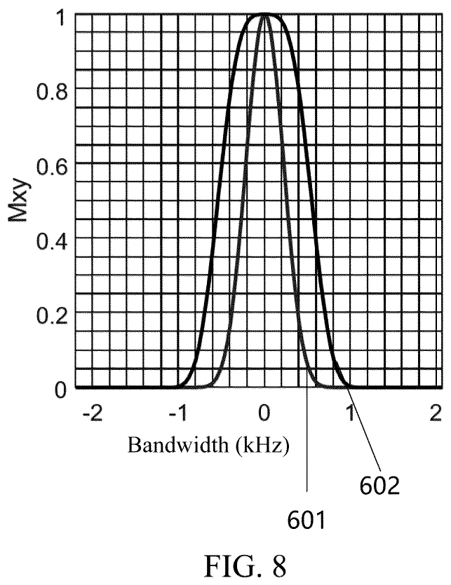

FIG. 7 is a time-domain schematic diagram of an original RF pulse and an adjusted RF pulse according to an embodiment of the present application. FIG. 8 is a frequency-domain schematic diagram of an original RF pulse and an adjusted RF pulse according to an embodiment of the present application. As shown in FIG. 7, using a 180° refocusing pulse being used as the RF pulse as an example, the number of zero-crossing points before adjustment is 2, the number of zero-crossing points after adjustment is 4, the time-bandwidth product of the adjusted RF pulse is greater than the time-bandwidth product of the RF pulse before adjustment, the duration of the adjusted RF pulse in the time domain is equal to the duration of the RF pulse before adjustment in the time domain, the maximum amplitude of the RF pulse before adjustment is, for example, 0.095 G, the maximum amplitude of the adjusted RF pulse is equal to the B1 maximum value, that is, 0.2 G, and the waveform area of the adjusted RF pulse in the time domain is equal to the waveform area of the RF pulse before adjustment in the time domain. As shown in FIG. 8, since the duration of the adjusted RF pulse in the time domain is equal to the duration of the RF pulse before adjustment in the time domain, the bandwidth of the adjusted RF pulse in the frequency domain is greater than the bandwidth of the RF pulse before adjustment in the frequency domain.

In some embodiments, by increasing the time-bandwidth product, the maximum amplitude of the adjusted RF pulse equals or asymptotically approaches the B1 maximum value, thereby achieving adjustment of the profile of the RF pulse. Optionally, the method may further comprise: a passband ripple coefficient or stopband ripple coefficient is adaptively adjusted based on the profile of the adjusted RF pulse, which is not repeated here.

In some embodiments, in 203, the waveform and timing of the RF pulses may be regenerated. As shown in FIG. 1, the transceiver 135 in the MRI system controller 130 generates the RF pulse amplified by RF power amplifier 162 and provides the RF pulse to the RF transmit coil 148 or 149 to transmit the regenerated RF pulses. Additionally, gradient sequences may be utilized to drive the gradient amplifier. The gradient amplifier excites a corresponding gradient coil to generate a magnetic field gradient used to spatially encode an MR signal during MRI scanning, so as to acquire a magnetic resonance signal and reconstruct a magnetic resonance image. For an image reconstruction method, reference may be made to the related art.

In some embodiments, if switching to a next scan subject to be scanned, then the aforementioned imaging method is performed again.

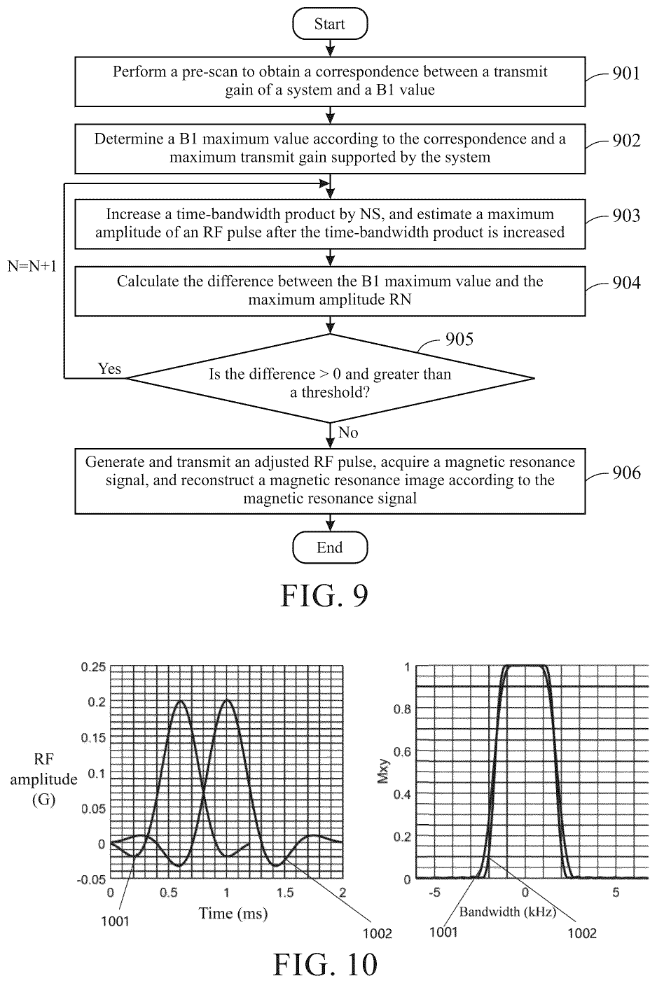

FIG. 9 illustrates a magnetic resonance imaging method according to one embodiment of the present application. In step 901, a pre-scan is performed to establish the relationship between the system's transmit gain and the corresponding B1 field value. Based on this, step 902 determines the maximum B1 value using the system's maximum supported transmit gain. In step 903, the time-bandwidth product of an RF pulse is increased by a factor of NS (starting with N=1), and the resulting maximum amplitude RN of the RF pulse is estimated. Step 904 calculates the difference between the maximum B1 value and the maximum amplitude RN. In step 905, if this difference is greater than zero and exceeds a predefined threshold, N is incremented (N=N+1) and the process loops back to step 903; otherwise, the adjustment ends. Finally, step 906 involves generating and transmitting the adjusted RF pulse, performing a diagnostic scan, acquiring the magnetic resonance signal, and reconstructing the image based on the acquired data.

Specific implementations of 901 to 906 are as previously described and are not repeated herein.

By means of the above embodiments, the profile of the RF pulse is adjusted according to the real-time B1 maximum value. As a result, the capability of the RF power amplifier can be fully utilized, the RF pulse waveform can be optimized, and a better excitation or spin echo or saturation profile can be obtained, thereby improving the image quality and reducing the scanning time.

In addition, in the embodiments of the present application, the time-bandwidth product of the RF pulse is adjusted based on the B1 maximum value. By increasing the time-bandwidth product, the maximum amplitude of the adjusted RF pulse equals or asymptotically approaches the B1 maximum value, thereby achieving adjustment of the profile of the RF pulse. Compared with an adjustment method implemented by only adjusting the maximum amplitude of the RF pulse to the B1 maximum value without changing the time-bandwidth product, the image quality can be further improved.

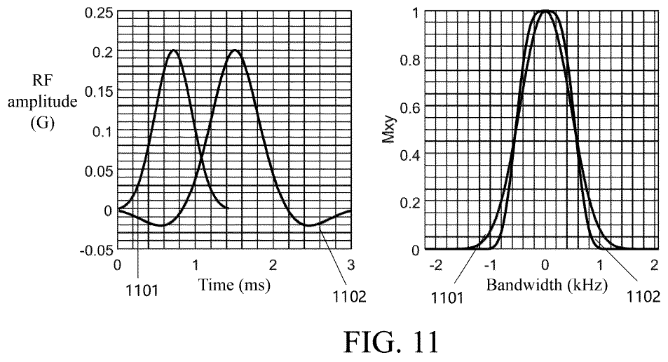

The following is described with reference to FIG. 10 and FIG. 11. FIG. 10 is time-domain and frequency-domain schematic diagrams of two types of RF pulses according to an embodiment of the present application. As shown in FIG. 10, using the excitation RF pulse in FIG. 5 as an example, only the maximum amplitude of the RF pulse is adjusted to the B1 maximum value without changing the time-bandwidth product to obtain a waveform 1001 (since the area needs to remain unchanged before and after adjustment, the time-domain duration of the waveform 1001 becomes shorter, and the waveform profile does not change), and the time-bandwidth product is increased and the maximum amplitude of the RF pulse is allowed to be equal to the B1 maximum value to obtain a waveform 1002. In the frequency domain, although there is an increase in bandwidth compared to an original excitation profile, the excitation profile of the waveform 1002 has a sharper transition band compared to the waveform 1001.

Therefore, the image quality can be further improved. FIG. 11 is time-domain and frequency-domain schematic diagrams of two types of RF pulses according to an embodiment of the present application. As shown in FIG. 11, using the refocusing RF pulse in FIG. 6 as an example, only the maximum amplitude of the RF pulse is adjusted to the B1 maximum value without changing the time-bandwidth product to obtain a waveform 1101 (since the area needs to remain unchanged before and after adjustment, the time-domain duration of the waveform 1101 becomes shorter, and the waveform profile does not change), and the time-bandwidth product is increased and the maximum amplitude of the RF pulse is equal to the B1 maximum value to obtain a waveform 1102. In the frequency domain, although there is an increase in bandwidth compared to an original excitation profile, the excitation profile of the waveform 1102 has a sharper transition band compared to the waveform 1101. Therefore, the image quality can be further improved.

The embodiments of the present application further provide a magnetic resonance imaging system. The configuration of the magnetic resonance imaging system is as shown in FIG. 1, and similarities are not repeated here.

In some embodiments, unlike the aforementioned medical imaging system in FIG. 1, the controller 130 is configured to determine a B1 maximum value of an RF field; adjust a profile of an RF pulse according to the B1 maximum value; and generate an adjusted RF pulse, provide the adjusted RF pulse to an RF transmit coil to transmit the regenerated RF pulse, control a receive coil to acquire a magnetic resonance signal, and reconstruct a magnetic resonance image according to the magnetic resonance signal.

In some embodiments, the controller 130 (which may also be a processor) includes a computer processor and a storage medium. The storage medium has recorded thereon a predetermined data processing program to be executed by the computer processor. For example, the storage medium may store a program configured to implement scanning processing (for example, including waveform design/conversion, and the like), image reconstruction, image processing, etc. For example, the storage medium may store a program configured to implement a method for determining an RF pulse waveform according to an embodiment of the present invention. The method includes: determining a B1 maximum value of an RF field; and adjusting a profile of an RF pulse according to the B1 maximum value. The specific implementations are as described above, and will not be repeated here. The described storage medium may include, for example, a ROM, a floppy disk, a hard disk, an optical disk, a magneto-optical disk, a CD-ROM, or a non-volatile memory card.

Embodiments of the present application further provide a method for determining an RF pulse waveform. The method includes: determining a B1 maximum value of an RF field; and adjusting a profile of an RF pulse according to the B1 maximum value. Moreover, as shown in FIG. 1, the transceiver 135 in the MRI system controller 130 generates the RF pulses amplified by the RF power amplifier 162 and provides the RF pulses to the RF transmit coil 148 or 149 to transmit the regenerated RF pulses. For the specific implementation, reference may be made to the foregoing embodiments, which will not be repeated here.

The embodiments of the present application further provide a computer-readable program. When the program is executed in an apparatus or an MRI system, the program enables a computer to perform, in the apparatus or the MRI system, the method according to the foregoing embodiments.

Further provided in the embodiments of the present application is a storage medium having a computer-readable program stored therein, wherein the computer-readable program causes a computer to execute, in an apparatus or an MRI system, the method according to the foregoing embodiments.

The embodiments of the present application further provide a computer program product, at least including a computer-readable program, wherein the computer-readable program causes a computer to execute, in an MRI system, the method according to the foregoing embodiments.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/apparatus described with reference to the embodiments of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for implementing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A magnetic resonance imaging method, characterized by comprising:
determining a B1 maximum value of a radio-frequency (RF) field;
adjusting a profile of an RF pulse according to the B1 maximum value; and
generating and transmitting an adjusted RF pulse, acquiring a magnetic resonance signal, and reconstructing a magnetic resonance image according to the magnetic resonance signal.

2. The method according to claim 1, wherein the RF pulse comprises at least one of an excitation pulse, a refocusing pulse, and a saturation pulse.

3. The method according to claim 1, wherein the adjusting a profile of an RF pulse according to the B1 maximum value comprises:
adjusting a time-bandwidth product of the RF pulse according to the B1 maximum value.

4. The method according to claim 3, wherein a time-bandwidth product of the adjusted RF pulse is greater than the time-bandwidth product of the RF pulse before adjustment.

5. The method according to claim 1, wherein the duration of the RF pulse before adjustment in the time domain is the same as the duration of the adjusted RF pulse in the time domain.

6. The method according to claim 1, wherein the bandwidth of the adjusted RF pulse in the frequency domain is greater than the bandwidth of the RF pulse before adjustment in the frequency domain.

7. The method according to claim 1, wherein a waveform area of the adjusted RF pulse in the time domain is equal to a waveform area of the RF pulse before adjustment in the time domain.

8. The method according to claim 3, wherein the adjusting a time-bandwidth product of the RF pulse according to the B1 maximum value comprises:
increasing the time-bandwidth product of the RF pulse, and estimating a maximum amplitude of the RF pulse after the time-bandwidth product is increased; and
when the difference between the B1 maximum value and the maximum amplitude is greater than 0 and is greater than a threshold, increasing the time-bandwidth product of the RF pulse again, and estimating the maximum amplitude of the RF pulse after the time-bandwidth product is increased until the difference between the B1 maximum value and the maximum amplitude is equal to 0 or less than the threshold.

9. The method according to claim 1, wherein the determining a B1 maximum value of an RF field comprises:
performing a pre-scan to obtain a correspondence between a transmit gain of a system and a B1 value; and
determining the B1 maximum value according to the correspondence and a maximum transmit gain supported by the system.

10. A magnetic resonance imaging system, characterized by comprising:
a scanning unit; and
a controller configured to perform the magnetic resonance imaging method according to claim 1.
